(19) United States
(12) Patent Application Publication
(10) Pub. No.: US 2013/0268821 A1
(43) Pub. Date: Oct. 10, 2013

(54) DECODING APPARATUS AND DECODING METHOD FOR DECODING DATA ENCODED BY LDPC

(71) Applicant: JVC KENWOOD CORPORATION, Yokohama-shi (JP)

(72) Inventor: Atsushi HAYAMI, Yokohama-shi (JP)

(21) Appl. No.: 13/830,415

(22) Filed: Mar. 14, 2013

Related U.S. Application Data
(63) Continuation of application No. PCT/JP2011/005290, filed on Sep. 20, 2011.

(30) Foreign Application Priority Data
Sep. 30, 2010 (JP) 2010-222985

(51) Int. Cl. H03M 13/05

(52) U.S. Cl. CPC H03M 13/05
USPC 714/752

(57) ABSTRACT

A data storage unit receives LDPC encoded data. A min-sum processing unit alternately executes, on the inputted data, check node processing for updating an external value ratio based on a priori value ratio and variable node processing for updating the priori value ratio based on the external value ratio, by executing a min-sum algorithm. A control unit adjusts, in accordance with the magnitude of the priori value ratio to be updated in the variable node processing, the magnitude of a normalization constant to be used in updating the external value ratio in the check node processing.

### BACKGROUND OF THE INVENTION

1. Field of the Invention

The present invention relates to a decoding technique, and more particularly to a decoding apparatus and a decoding method for decoding data encoded by LDPC.

2. Description of the Related Art

In recent years, LDPC (Low Density Parity Check Code) attracts attention as an error correction code having high error correction performance even in a transmission path with a low S/N, and the LDPC is applied in many fields. In the LDPC, data is encoded with an encoding matrix generated based on s sparse check matrix on a transmission side. Herein, the sparse check matrix is a matrix in which elements are either 1 or 0 and the number of 1s is small. On the other hand, data is decoded and parity check is performed based on the check matrix on a receiving side. In particular, the decoding performance is improved by iterative decoding according to BP (Belief Propagation) method, etc.

In this decoding, check node processing for decoding in a row direction of the check matrix and variable node processing for decoding in a column direction are repeatedly executed. Sum-product decoding using Gallager or hyperbolic functions is known as one of the check node processing. In the sum-product decoding, a communication path value obtained from a distribution value of transmission path noise is used as a priori value. A simplified decoding method of the sum-product decoding is min-sum decoding. In the min-sum decoding, check node processing can be performed by performing simple processing, such as comparison operation and summation operation, without using complicated functions. Further, because the min-sum decoding does not require a communication path value, it is widely used for simplifying the processing and increasing the speed thereof. In order to reduce the circuit magnitude of min-sum decoding, using the smallest and the second smallest priori value ratios in each row of a check matrix, is proposed.

The min-sum decoding is achieved more simply than the sum-product decoding. On the other hand, there is the general tendency that the decoding characteristic of the min-sum decoding is more deteriorated than that of the sum-product decoding. Accordingly, it is desired that the decoding characteristic of the min-sum decoding is improved while an increase in the circuit magnitude thereof is being suppressed.

### SUMMARY OF THE INVENTION

The present invention has been made in view of these situations, and a purpose of the invention is to provide a technique in which the decoding characteristic of the min-sum decoding is improved.

In order to solve the aforementioned problem, a decoding apparatus according to an aspect of the present invention comprises: an input unit configured to input encoded data; a decoding unit configured to alternately execute, on the data inputted by the input unit, check node processing for updating an external value ratio based on a priori value ratio and variable node processing for updating the priori value ratio based on the external value ratio, by executing a min-sum algorithm; and a control unit configured to adjust, in accordance with the magnitude of the priori value ratio to be updated in the variable node processing in the decoding unit, the magnitude of a normalization constant to be used in updating the external value ratio in the check node processing.

According to this aspect, the magnitude of a normalization constant is adjusted in accordance with the magnitude of a priori value ratio, and hence decoding characteristic can be improved by using a normalization constant in which the probability of a priori value ratio has been reflected.

The control unit may make the normalization constant to be larger as the magnitude of the priori value ratio becomes larger. In this case, because an influence by a priori value ratio, occurring when an external value ratio is updated, becomes larger as the probability of the priori value ratio becomes larger, decoding characteristic can be improved.

The control unit may include: a storage unit configured to store a plurality of normalization constants; and a selection unit configured to select, based on the magnitude of a priori value ratio to be updated in the variable node processing in the decoding unit, one of the plurality of normalization constants stored in the storage unit. In this case, because one of the plurality of normalization constants that have been stored is selected, complication of the processing can be suppressed.

Another aspect of the present invention is a decoding method. This method comprises: inputting encoded data; alternately executing, on the inputted data, check node processing for updating an external value ratio based on a priori value ratio and variable node processing for updating the priori value ratio based on the external value ratio, by executing a min-sum algorithm; and adjusting, in accordance with the magnitude of the priori value ratio to be updated in the variable node processing, the magnitude of a normalization constant to be used in updating the external value ratio in the check node processing.

In the above adjustment, the normalization constant may be made larger as the magnitude of the priori value ratio becomes larger.

In the above adjustment, one of the plurality of normalization constants stored in a memory may be selected based on the magnitude of the priori value ratio to be updated in the variable node processing.

It is noted that any combination of the aforementioned components or any manifestation of the present invention realized by modifications of a method, apparatus, system, storing media, computer program, and so forth, is effective as an aspect of the present invention.

### BRIEF DESCRIPTION OF THE DRAWINGS

Embodiments will now be described, byway of example only, with reference to the accompanying drawings which are meant to be exemplary, not limiting, and wherein like elements are numbered alike in several Figures, in which:

FIG. 1 is a view illustrating the structure of a communication system according to an embodiment of the present invention;

FIG. 2 is a view illustrating a check matrix to be used in an LDPC encoding unit in FIG. 1;

FIG. 3 is a view illustrating the structure of a decoding unit in FIG. 1;

FIG. 4 is a view illustrating a Tanner graph schematically indicating the operations of the decoding unit in FIG. 3;

FIG. 5 is a view illustrating the outline of an external value ratio in the decoding unit in FIG. 3;

FIG. 6 is a view illustrating the outline of update of a priori value ratio in the decoding unit in FIG. 3;

FIG. 7 is a graph showing a BER characteristic in a reception apparatus in FIG. 1; and

FIG. 8 is a flowchart indicating decoding procedures in the decoding unit in FIG. 3.

### DETAILED DESCRIPTION OF THE INVENTION

The invention will now be described by reference to the preferred embodiments. This does not intend to limit the scope of the present invention, but to exemplify the invention.

Before the present invention is described specifically, the outline thereof will be first stated. An embodiment of the invention relates to a communication system including a transmission apparatus for executing LDPC encoding and a reception apparatus for executing, on the data encoded in the transmission apparatus (hereinafter, referred to as “encoded data”), iterated decoding based on a check matrix. In particular, the reception apparatus executes a min-sum algorithm. Although a min-sum algorithm is achieved with simple processing, as stated above, the decoding characteristic thereof is likely to be deteriorated. In order to improve the decoding characteristic while an increase in the processing amount is being suppressed, the communication system according to the present embodiment, in particular, the reception apparatus is formed as follows.

In a min-sum algorithm, the accuracy of the decoding is improved by repeatedly executing check node processing and variable node processing. The check node processing updates an external value ratio based on a priori value ratio by using a normalization constant. The reception apparatus according to the present embodiment determines a normalization constant based on the magnitude of a priori value ratio. In that case, a plurality of normalization constants are stored in advance and one of them is selected. Further, the reception apparatus executes check node processing by using the determined normalization constant.

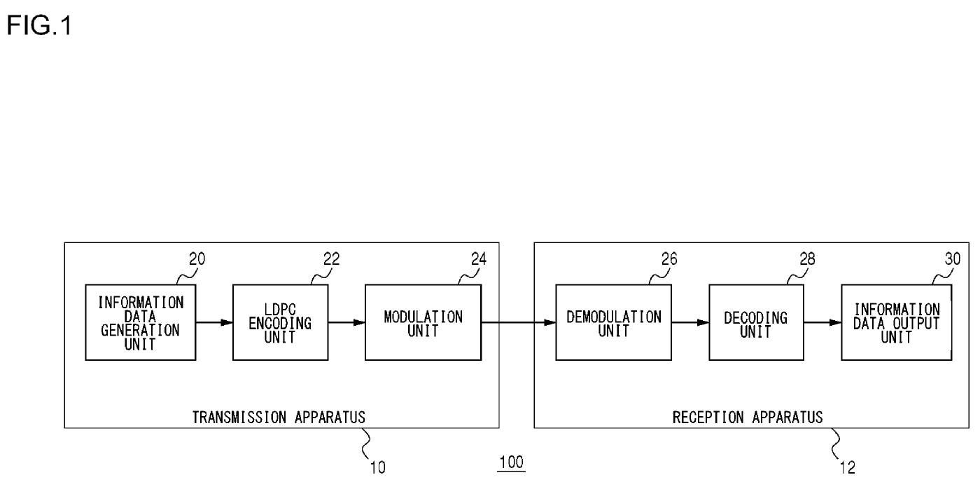

FIG. 1 is a view illustrating the structure of the communication system 100 according to an embodiment of the present invention. The communication system 100 includes the transmission apparatus 10 and the reception apparatus 12. The transmission apparatus 10 includes an information data generation unit 20, an LDPC encoding unit 22, and a modulation unit 24. The reception apparatus 12 includes a demodulation unit 26, a decoding unit 28, and an information data output unit 30.

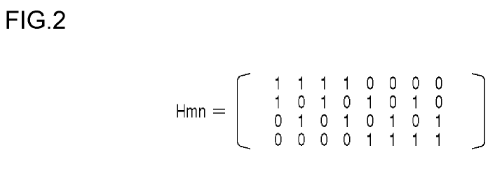

The information data generation unit 20 acquires data to be transmitted and generates information data. Alternatively, the acquired data may be used as the information data as it is. The information data generation unit 20 outputs the information data to the LDPC encoding unit 22. The LDPC encoding unit 22 receives the information data from the information data generation unit 20. The LDPC encoding unit 22 attaches a parity based on a check matrix by the LDPC (hereinafter, referred to as an “LDPC parity”) to the information data. The information data to which the LDPC parity has been attached is equivalent to the aforementioned encoded data. The LDPC encoding unit 22 outputs the encoded data to the modulation unit 24. FIG. 2 illustrates a check matrix to be used in the LDPC encoding unit 22. The check matrix Hmn is a matrix having m rows and n columns. Herein, in order to make the description clear, the check matrix Hmn is made to have 4 rows and 8 columns, but the check matrix is not limited thereto. Reference is made to FIG. 1 again.

The modulation unit 24 receives the encoded data from the LDPC encoding unit 22. The modulation unit 24 modulates the encoded data. As modulation methods, PSK (Phase Shift Keying), FSK (Frequency Shift Keying), etc., are used. The modulation unit 24 transmits the modulated encoded data as a modulated signal. The demodulation unit 26 receives the modulated signal from the modulation unit 24 via a communication path, for example, a wireless transmission path. The demodulation unit 26 demodulates the modulated signal. A publicly-known technique may be used for the demodulation, and hence description thereof will be omitted. The demodulation unit 26 outputs a demodulation result (hereinafter, referred to as “demodulated data”) to the decoding unit 28.

The decoding unit 28 receives the demodulated data from the demodulation unit 26. The decoding unit 28 repeatedly executes, on the demodulated data, decoding processing with the check matrix by the LDPC. For example, a min-sum algorithm is executed as the decoding processing. The min-sum algorithm is executed in the following procedures.
1. Initialization: a priori value ratio is initialized and the maximum number of repetitions of decoding is set.
2. Check node processing: an external value ratio is updated in the row direction of the check matrix.
3. Variable node processing: the priori value ratio is updated in the column direction of the check matrix.
4. A temporary estimated word is calculated.

Detailed description of these procedures will be omitted; however, a normalization constant is used in the later-described check node processing. The decoding unit 28 determines a normalization constant based on the priori value ratio updated in the variable node processing; however, detailed description thereof will be omitted. The decoding unit 28 outputs a decoding result (hereinafter, referred to as “decoded data”) to the information data output unit 30. The information data output unit 30 receives the decoded data from the decoding unit 28. The information data output unit 30 generates information data based on the decoded data. Alternatively, the decoded data may be used as the information data as it is. The information data output unit 30 may include an outer code decoding unit such that an outer code, such as, for example, CRC (Cyclic Redundancy Check), is decoded.

This structure is implemented in hardware by any CPU of a computer, memory, and other LSI, and implemented in software by a computer program or the like that is loaded in a memory. Herein, functional blocks implemented by the cooperation of hardware and software are depicted. Accordingly, it can be understood by those skilled in the art that these functional blocks may be implemented in a variety of manners by hardware only, software only, or any combination thereof.

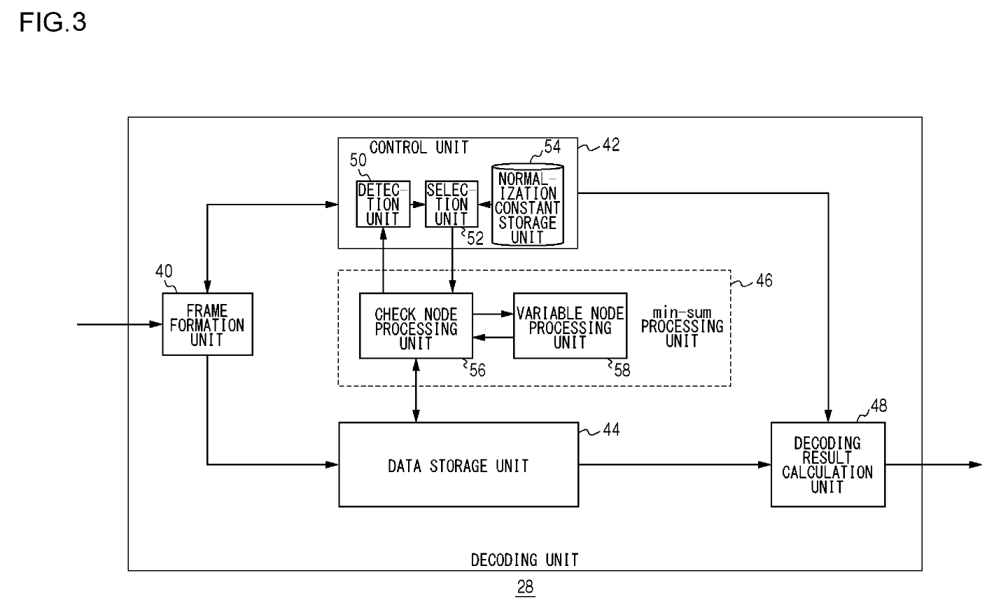

FIG. 3 illustrates the structure of the decoding unit 28. The decoding unit 28 includes a frame formation unit 40, a control unit 42, a data storage unit 44, a min-sum processing unit 46, and a decoding result calculation unit 48. In addition, the control unit 42 includes a detection unit 50, a selection unit 52, and a normalization constant storage unit 54, and the min-sum lo processing unit 46 includes a check node processing unit 56 and a variable node processing unit 58.

The frame formation unit 40 receives the demodulated data from the non-illustrated demodulation unit 26. It can be said that the demodulated data is LDPC encoded data via a communication path. The frame formation unit 40 detects a frame synchronization signal included in the demodulated data. The frame formation unit 40 identifies, based on the frame synchronization signal, a unit of a frame formed by the demodulated data. For example, when the frame synchronization signal is arranged at the head portion of a frame, and when the period of the frame is a fixed length, the frame formation unit 40 identifies the period of the fixed length from when the frame synchronization signal has been detected as a frame. Alternatively, the unit of the LDPC encoding may be a frame. The frame formation unit 40 makes the data storage unit 44 store the demodulated data collected in units of frames. The data storage unit 44 temporarily stores demodulated signals in units of frames.

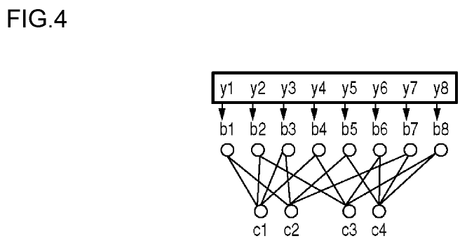

The min-sum processing unit 46 receives the demodulated data from the data storage unit 44 and receives the normalization constant from the selection unit 52. The min-sum processing unit 46 uses the normalization constant to execute a min-sum algorithm on the demodulated data. In the min-sum algorithm, the check node processing unit 56 and the variable node processing unit 58 are alternately executed. FIG. 4 illustrates a Tanner graph schematically indicating the operations of the decoding unit 28. In the Tanner graph, b1 to b8 are referred to as variable nodes and c1 to c4 are referred to as check nodes. Herein, the number of the variable nodes is made to be n, and bn is made to be an n-th variable node. In addition, the number of the check nodes is made to be m, and cm is made to be an m-th check node. Data y1 to y8 stored in the data storage unit 44 in FIG. 3 are linked to the variable nodes b1 to b8, respectively. Reference is made to FIG. 3 again.

The check node processing unit 56 receives the normalization constant from the selection unit 52 and initializes a priori value ratio β at the beginning of the iterative decoding. Herein, the demodulated data stored by the data storage unit 44 is used as it is. Subsequently, the check node processing unit 56 determines the lowest absolute value min|βmn′| of the priori value ratios. The check node processing unit 56 updates an external value ratio αmn from cm to bm with a variable node linked to a check node. For every group(m,n) satisfying check matrix Hmn=1, αmn is calculated as follows.

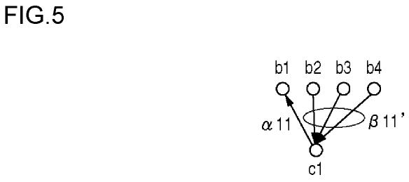

αmn=a(Π sign(βmn′))*min|βmn′| (1)

Wherein, n′ represents A(m)¥n, in which A(m) is a set of variable nodes linked to the check node m and ¥n represents a difference set not including n; sign represents a signature function; min|βmn′| represents the lowest absolute value selection; and a represents a normalization constant. FIG. 5 illustrates the outline of the update of an external value ratio in the decoding unit 28. The external value ratio α11 is derived from β11′. That is, the check node processing unit 56 updates an external value ratio based on a priori value ratio. Reference is made to FIG. 3 again. The derivation of the lowest absolute value min|βmn′| of the priori value ratios is performed for every repetition.

The variable node processing 58 updates a priori value ratio βmn from bn to cm with a check node linked to a variable node. For every group(m,n) satisfying check matrix Hmn=1, βmn is calculated as follows:

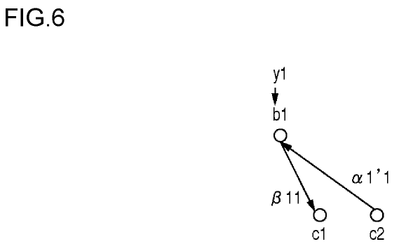

βmn=Σαm′n+λn (2)

Wherein, λn is equal to input data yn. The input data yn corresponds to the demodulated data from the demodulation unit 26. m′ represents B(n)¥m, in which B(n) is a set of check nodes lined to the variable node n and ¥m represents a difference set not including m. FIG. 6 illustrates the outline of the update of a priori value ratio in the decoding unit 28. The priori value ratio β11 is derived from α1′1. That is, the variable node processing unit 58 updates a priori value ratio based on an external value ratio. Reference is made to FIG. 3 again.

The detection unit 50 receives, from the check node processing unit 56, the lowest absolute value min|βmn′| of the priori value ratios to be used in the check mode processing. It can be said that this value is the magnitude of the priori value ratio to be updated by the variable node processing unit 58. The detection unit 50 selects one of the lowest absolute values min|βmn′|s of a plurality of the priori value ratios to be used in one time of the check node processing. The detection unit 50 outputs the selected lowest absolute value to the selection unit 52. The normalization constant storage unit 54 stores a plurality of normalization constants. Herein, a first normalization constant and a second normalization constant are stored as two normalization constants. For example, the first normalization constant is “0.65” and the second normalization constant is “0.72”. That is, the second normalization constant is larger than the first normalization constant.

The selection unit 52 receives the lowest absolute value from the detection unit 50. The selection unit 52 compares the lowest absolute value and the threshold value to select, based on the comparison result, one of the plurality of the normalization constants stored by the normalization constant storage unit 54. For example, the threshold value is “0.5”. Specifically, when the lowest absolute value is smaller than 0.5, the selection unit 52 selects the first normalization constant, and when the lowest absolute value is 0.5 or more, the selection unit 52 selects the second normalization constant. Accordingly, a larger normalization constant is selected as the magnitude of an absolute value of a priori value ratio becomes larger.

The probability of a priori value ratio is reflected in the magnitude of the absolute value of the priori value ratio. On the other hand, as shown in the equation (1), a normalization constant corresponds to the degree of an influence by a priori value ratio, occurring when an external value ratio is updated. When the probability of a priori value ratio is high, an influence by the priori value ratio, occurring when an external value ratio is updated, is made large, and when the probability of a priori value ratio is low, an influence by the priori value ratio, occurring when an external value ratio is updated, is made small. As a result, decoding characteristic can be improved with the accuracy of updating an external value ratio being improved.

The selection unit 52 outputs the selected normalization constant to the check node processing unit 56. The selected normalization constant is used for the update of the external value ratio α in the check node processing unit 56. Thus, the control unit 42 adjusts, in accordance with the magnitude of the priori value ratio to be updated in the variable node processing unit 58, the magnitude of a normalization constant to be used in updating the external value ratio in the check node processing unit 56.

After the processing in the check node processing unit 56 and the processing in the variable node processing unit 58 have been repeated predetermined times, the decoding result calculation unit 48 calculates a temporary estimated word. Alternatively, when a result of the parity check is right, the decoding result calculation unit 48 may calculate a temporary estimated word, even before the above processing are repeated the lo predetermined times. The decoding result calculation unit 48 may output the temporary estimated word as a decoding result.

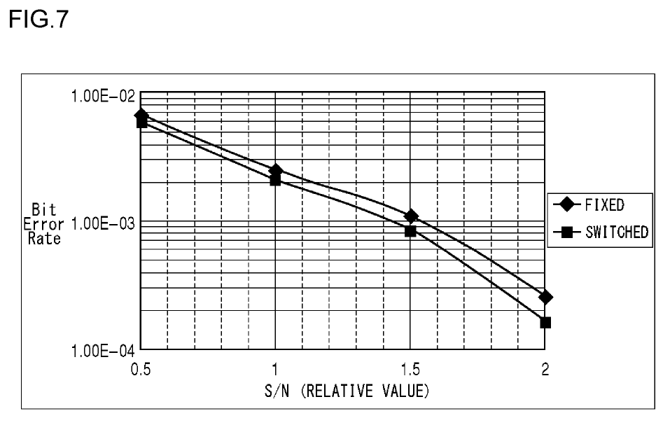

FIG. 7 is a graph showing a BER characteristic of the reception apparatus 12. In FIG. 7, the horizontal axis represents relative values of S/N of the transmission path, while the vertical axis represents bit error rates. The diamond-shaped marks correspond to the case where check node processing is executed by fixing a normalization constant to 0.72, while square-shaped marks correspond to the case where, as in the decoding unit 28 in FIG. 3, check node processing is executed by switching to the first normalization constant or the second normalization constant. When a normalization constant is switched, decoding characteristic is more improved in comparison with the case where a normalization constant is fixed, irrespective of the magnitude of added noise.

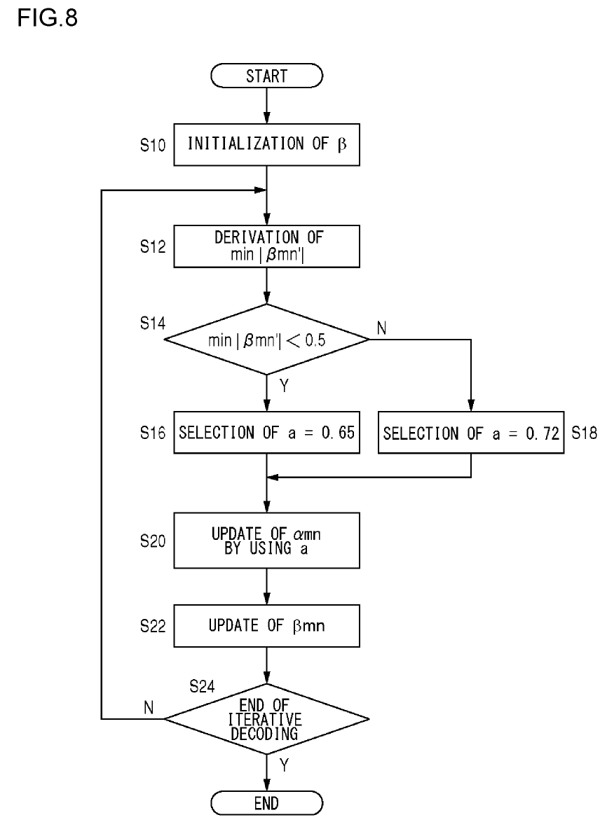

The operations of the communication system 100 having the aforementioned structure will be described. FIG. 8 is a flowchart indicating decoding procedures in the decoding unit 28. The check node processing unit 56 initializes the priori value ratio β (S10). The check node processing unit 56 derives min|βmn′| (S12). When the min|βmn′| is smaller than a threshold value of 0.5 (S14/Y), the selection unit 52 selects the first normalization constant of 0.65 as a normalization constant a (S16). On the other hand, when the min|βmn′| is not smaller than the threshold value of 0.5 (S14/N), the selection unit 52 selects the second normalization constant of 0.72 as a normalization constant a (S18). The check node processing unit 56 updates the external value ratio αmn by using the normalization constant a (S20). The variable node processing unit 58 updates the priori value ratio βmn by using the external value ratio αmn (S22). When iterative decoding is not ended (S24/N), the step 12 is performed again. When the iterative decoding is ended (S24/Y), the processing is ended.

According to the present embodiment, the magnitude of a normalization constant is adjusted in accordance with the magnitude of a priori value ratio, and hence a normalization constant, in which the probability of a priori value ratio has been reflected, can be used in updating the external value ratio. Further, because a normalization constant, in which the probability of a priori value ratio has been reflected, is used, decoding characteristic can be improved. Furthermore, because a normalization constant is made larger as the magnitude of a priori value ratio becomes larger, an influence by a priori value ratio, occurring when an external value ratio is updated, can be made larger as the probability of the priori value ratio becomes higher. Furthermore, because a normalization constant is made smaller as the magnitude of a priori value ratio becomes smaller, an influence by a priori value ratio, occurring when an external value ratio is updated, can be made smaller as the probability of the priori value ratio becomes smaller. Furthermore, because one of a plurality of normalization constants that have been stored is selected, complication of the processing can be suppressed. Furthermore, because the lowest value to be used for selecting a normalization constant is already derived in the check node processing, addition of new processing can be made small.

The present invention has been described above based on embodiments. The embodiments are described for exemplary purposes only, and it can be readily understood by those skilled in the art that various modifications may be made by making various combinations of the aforementioned components or processes, which are also encompassed by the scope of the present invention.

It is assumed that the communication system 100 according to an embodiment of the present invention relates to a wireless communication system, and hence the transmission apparatus 10 and the reception apparatus 12 are included in a wireless communication apparatus. However, the communication system 100 is not limited thereto, but it may be assumed that the communication system 100 relates to a wired communications system. In that case, the transmission apparatus 10 and the reception apparatus 12 are included in a wired communication apparatus. According to the present variation, the invention can be applied to various apparatuses.

In an embodiment of the present invention, the number of the normalization constants, which have been stored by the normalization constant storage unit 54 and are to be selected by the selection unit 52, is made to be 2. However, the number is not limited thereto, but may be 3 or more. In that case, threshold values, the number of which is set in accordance with the number of the normalization constants, are also specified in the selection unit 52. According to the present variation, normalization constants can be set in detail.

In an embodiment of the present invention, the transmission apparatus 10 executes LDPC encoding. However, the transmission apparatus 10 is not limited thereto, but may execute, even other than by LDPC, encoding in which a min-sum algorithm can be executed when being decoded. According to the present variation, the invention can be applied to various encoding.

1. A decoding apparatus comprising:
an input unit configured to input encoded data;
a decoding unit configured to alternately execute, on the data inputted by the input unit, check node processing for updating an external value ratio based on a priori value ratio and variable node processing for updating the priori value ratio based on the external value ratio, by executing a min-sum algorithm; and
a control unit configured to adjust, in accordance with the magnitude of the priori value ratio to be updated in the variable node processing in the decoding unit, the magnitude of a normalization constant to be used in updating the external value ratio in the check node processing.

2. The decoding apparatus according to claim 1, wherein
the control unit makes the normalization constant to be larger as the magnitude of the priori value ratio becomes larger.

3. The decoding apparatus according to claim 1, wherein
the control unit includes:
a storage unit configured to store a plurality of normalization constants; and
a selection unit configured to select, based on the magnitude of a priori value ratio to be updated in the variable node processing in the decoding unit, one of the plurality of normalization constants stored in the storage unit.

4. A decoding method comprising:
inputting encoded data;
alternately executing, on the inputted data, check node processing for updating an external value ratio based on a priori value ratio and variable node processing for updating the priori value ratio based on the external value ratio, by executing a min-sum algorithm; and
adjusting, in accordance with the magnitude of the priori value ratio to be updated in the variable node processing, the magnitude of a normalization constant to be used in updating the external value ratio in the check node processing.

5. The decoding method according to claim 4, wherein
in the adjustment, the normalization constant is made larger as the magnitude of the priori value ratio becomes larger.

6. The decoding method according to claim 4, wherein in the adjustment, one of a plurality of normalization constants stored in a memory is selected based on the magnitude of the priori value ratio to be updated in the variable node processing.
